(19) United States
(12) Patent Application Publication
(10) Pub. No.: US 2014/0097410 A1
(43) Pub. Date: Apr. 10, 2014

(54) THIN FILM TRANSISTOR SUBSTRATE, METHOD OF REPAIRING THE THIN FILM TRANSISTOR SUBSTRATE, ORGANIC LIGHT EMITTING DISPLAY APPARATUS, AND METHOD OF REPAIRING THE ORGANIC LIGHT EMITTING DISPLAY APPARATUS

(71) Applicants: Myoung-Su CHOI, Yongin-City (KR); Guang-Hai JIN, Yongin-City (KR)

(72) Inventors: Myoung-Su CHOI, Yongin-City (KR); Guang-Hai JIN, Yongin-City (KR)

(21) Appl. No.: 13/799,510

(22) Filed: Mar. 13, 2013

(30) Foreign Application Priority Data
Oct. 5, 2012 (KR) 10-2012-0110691

(51) Int. Cl. H01L 29/66; H01L 29/786; H01L 51/56; H01L 51/52

(52) U.S. Cl. CPC H01L 29/6675; H01L 51/52; H01L 29/786; H01L 51/56
USPC 257/40; 257/59; 257/71; 257/296; 438/4

(57) ABSTRACT

A thin film transistor substrate includes a capacitor including a first capacitor electrode and a second capacitor electrode on a substrate, a first wire connected to the first capacitor electrode, a second wire connected to the second capacitor electrode, a first conductive pattern layer spaced apart from the first capacitor electrode and the second capacitor electrode, a second conductive pattern layer spaced apart from the first conductive pattern layer and formed to overlap with the first conductive pattern layer, a first conductive wire pattern connected to the first conductive pattern layer, spaced apart from the second conductive pattern layer, and overlapping with the second wire in at least one area, and a second conductive wire pattern connected to the second conductive pattern layer, spaced apart from the first conductive pattern layer and the first conductive wire pattern, and overlapping with the first wire in at least one area.

### CROSS-REFERENCE TO RELATED PATENT APPLICATION

This application claims the benefit of Korean Patent Application No. 10-2012-0110691, filed on Oct. 5, 2012, in the Korean Intellectual Property Office, the disclosure of which is incorporated herein in its entirety by reference.

### BACKGROUND

Display apparatuses are been replaced with portable thin film flat panel display apparatuses. An organic light emitting display apparatus is a self-emitting display apparatus, and the organic light emitting display apparatus has drawn attention as a next-generation display apparatus.

### SUMMARY

Embodiments may be realized by providing a thin film transistor (TFT) substrate that includes a substrate; a TFT formed on the substrate and including an active layer, a gate electrode insulated from the active layer, and a source electrode and a drain electrode that are spaced apart from the gate electrode and connected to the active layer; a capacitor formed on the substrate and including a first capacitor electrode and a second capacitor electrode; a first wire connected to the first capacitor electrode so as to apply a voltage to the first capacitor electrode; a second wire connected to the second capacitor electrode so as to apply a voltage to the second capacitor electrode; a first conductive pattern layer spaced apart from the first capacitor electrode and the second capacitor electrode; a second conductive pattern layer spaced apart from the first conductive pattern layer and formed to overlap with the first conductive pattern layer; a first conductive wire pattern connected to the first conductive pattern layer, spaced apart from the second conductive pattern layer, and overlapping with the second wire in at least one area; and a second conductive wire pattern connected to the second conductive pattern layer, spaced apart from the first conductive pattern layer and the first conductive wire pattern, and overlapping with the first wire in at least one area.

The first conductive pattern layer and the first capacitor electrode may be formed on the same layer and formed of the same material. The second conductive pattern layer and the second capacitor electrode may be formed on the same layer and formed of the same material. The first conductive pattern layer and the gate electrode may be formed on the same layer and formed of the same material. The second conductive pattern layer and the source electrode or the drain electrode may be formed on the same layer and formed of the same material.

When a short circuit defect occurs in the capacitor due to particles and other impurities disposed between the first capacitor electrode and the second capacitor electrode, a voltage application to the capacitor may be blocked, and the first conductive pattern layer and the second conductive pattern layer may constitute a repair capacitor by replacing a function of the capacitor.

A first cutting portion may be formed in an area closer to the second capacitor electrode than an area that overlaps with the first conductive wire pattern in an area of the second wire, and a second cutting portion may also be formed in an area closer to the first capacitor electrode than an area that overlaps with the second conductive wire pattern in an area of the first wire.

The TFT substrate may further include a first welding portion formed at a location where the second wire and the first conductive wire pattern overlap with each other to connect the first conductive wire pattern and the second wire; and a second welding portion formed at a location where the first wire and the second conductive wire pattern overlap with each other to connect the second wire pattern and the first wire. The first conductive pattern layer or the second conductive pattern layer may perform a dummy pattern function in a case where no short circuit defect occurs in the capacitor.

Embodiments may also be realized by providing a method of repairing a TFT substrate that includes a substrate, a TFT formed on the substrate, a capacitor formed on the substrate and including a first capacitor electrode and a second capacitor electrode, a first conductive pattern layer spaced apart from the first capacitor electrode and the second capacitor electrode, a second conductive pattern layer spaced apart from the first conductive pattern layer and formed to overlap with the first conductive pattern layer, a first conductive wire pattern connected to the first conductive pattern layer and spaced apart from the second conductive pattern layer, and a second conductive wire pattern connected to the second conductive pattern layer and spaced apart from the first conductive pattern layer and the first conductive wire pattern. The method includes, when a short circuit defect occurs in the capacitor due to particles and other impurities disposed between the first capacitor electrode and the second capacitor electrode, blocking a voltage from being applied to the capacitor; and using the first conductive pattern layer and the second conductive pattern layer as a repair capacitor by replacing a function of the capacitor.

The blocking of the voltage from being applied to the capacitor may include forming a first cutting portion by cutting an area closer to the second capacitor electrode than an area that overlaps with the first conductive wire pattern by using a cutting member in an area of the second wire formed to apply a voltage to the second capacitor electrode, and forming a second cutting portion by cutting an area closer to the first capacitor electrode than an area that overlaps with the second conductive wire pattern by using the cutting member in an area of the first wire formed to apply a voltage to the first capacitor electrode.

The method may further include forming a first welding portion at a location where the second wire and the first conductive wire pattern overlap with each other by irradiating energy so as to connect the first conductive wire pattern and the second wire, and forming a second welding portion formed at a location where the first wire and the second wire pattern overlap with each other by irradiating energy so as to connect the second conductive wire pattern and the first wire.

Embodiments may also be realized by providing an organic light emitting display apparatus that includes a substrate; an organic light emitting device (OLED) formed on the substrate and including a first electrode, a second electrode, and an intermediate layer disposed between the first electrode and the second electrode and including at least an organic emissive layer; a capacitor formed on the substrate and including a first capacitor electrode and a second capacitor electrode; a first wire connected to the first capacitor electrode so as to apply a voltage to the first capacitor electrode; a second wire connected to the second capacitor electrode so as to apply a voltage to the second capacitor electrode; a first conductive pattern layer spaced apart from the first capacitor electrode and the second capacitor electrode; a second conductive pattern layer spaced apart from the first conductive pattern layer and formed to overlap with the first conductive pattern layer; a first conductive wire pattern connected to the first conductive pattern layer, spaced apart from the second conductive pattern layer, and overlapping with the second wire in at least one area; and a second conductive wire pattern connected to the second conductive pattern layer, spaced apart from the first conductive pattern layer and the first conductive wire pattern, and overlapping with the first wire in at least one area.

The first conductive pattern layer and the first capacitor electrode may be formed on the same layer and formed of the same material. The second conductive pattern layer and the second capacitor electrode may be formed on the same layer and formed of the same material.

The organic light emitting display apparatus may further include a TFT formed on the substrate and including an active layer, a gate electrode insulated from the active layer, and a source electrode and a drain electrode that are spaced apart from the gate electrode and connected to the active layer, wherein the first conductive pattern layer and the gate electrode are formed on the same layer and formed of the same material.

The organic light emitting display apparatus may further include a TFT formed on the substrate and including an active layer, a gate electrode insulated from the active layer, and a source electrode and a drain electrode that are spaced apart from the gate electrode and connected to the active layer, wherein the second conductive pattern layer and the source electrode or the drain electrode are formed on the same layer and formed of the same material.

When a short circuit defect occurs in the capacitor due to particles and other impurities disposed between the first capacitor electrode and the second capacitor electrode, a voltage application to the capacitor may be blocked, and the first conductive pattern layer and the second conductive pattern layer may constitute a repair capacitor by replacing a function of the capacitor.

A first cutting portion may be formed in an area closer to the second capacitor electrode than an area that overlaps with the first conductive wire pattern in an area of the second wire, and a second cutting portion may also be formed in an area closer to the first capacitor electrode than an area that overlaps with the second conductive wire pattern in an area of the first wire.

The organic light emitting display apparatus may further include: a first welding portion formed at a location where the second wire and the first conductive wire pattern overlap with each other to connect the first conductive wire pattern and the second wire; and a second welding portion formed at a location where the first wire and the second wire pattern overlap with each other to connect the second wire pattern and the first wire. The capacitor may be disposed at a display area in which an image of the organic light emitting display apparatus is implemented.

Embodiments may also be realized by providing a method of repairing an organic light emitting display apparatus that includes a substrate, an organic light emitting device (OLED) formed on the substrate and including a first electrode, a second electrode, and an intermediate layer disposed between the first electrode and the second electrode and including at least an organic emissive layer, a capacitor formed on the substrate and including a first capacitor electrode and a second capacitor electrode, a first conductive pattern layer spaced apart from the first capacitor electrode and the second capacitor electrode, a second conductive pattern layer spaced apart from the first conductive pattern layer and formed to overlap with the first conductive pattern layer, a first conductive wire pattern connected to the first conductive pattern layer and spaced apart from the second conductive pattern layer, and a second conductive wire pattern connected to the second conductive pattern layer and spaced apart from the first conductive pattern layer and the first conductive wire pattern. The method includes, when a short circuit defect occurs in the capacitor due to particles and other impurities disposed between the first capacitor electrode and the second capacitor electrode, blocking a voltage from being applied to the capacitor; and using the first conductive pattern layer and the second conductive pattern layer as a repair capacitor by replacing a function of the capacitor.

The blocking of the voltage from being applied to the capacitor may include: forming a first cutting portion by cutting an area closer to the second capacitor electrode than an area that overlaps with the first conductive wire pattern by using a cutting member in an area of the second wire formed to apply a voltage to the second capacitor electrode; and forming a second cutting portion by cutting an area closer to the first capacitor electrode than an area that overlaps with the second conductive wire pattern by using the cutting member in an area of the first wire formed to apply a voltage to the first capacitor electrode.

The method may further include forming a first welding portion at a location where the second wire and the first conductive wire pattern overlap with each other by irradiating energy so as to connect the first conductive wire pattern and the second wire; and forming a second welding portion formed at a location where the first wire and the second conductive wire pattern overlap with each other by irradiating energy so as to connect the second wire pattern and the first wire.

### BRIEF DESCRIPTION OF THE DRAWINGS

Features will become apparent to one of ordinary skill in the art by describing in detail exemplary embodiments thereof with reference to the attached drawings in which:

FIG. 1 is a schematic cross-sectional view of a thin film transistor (TFT) substrate according to an exemplary embodiment;

FIG. 2 is a top plan view of a region A in FIG. 1;

FIG. 3 is a plan view of a capacitor of FIGS. 1 and 2, in which a short circuit defect has occurred;

FIG. 4 is a cross sectional view taken along a line IX-IX in FIG. 3;

FIGS. 5 and 6 are plan views for depicting stages in a method of repairing a TFT substrate of FIG. 3;

FIG. 7 is a cross sectional view taken along a line VII-VII of FIG. 6;

FIGS. 8 through 10 are schematic circuit diagrams for depicting stages in a method of repairing a short circuit defect that occurs in a TFT substrate of FIG. 1;

FIG. 11 is a schematic cross-sectional view of an organic light emitting display apparatus, according to an exemplary embodiment;

FIG. 12 is a top plan view of a region A in FIG. 11; and

FIG. 13 is a plan view for explaining a method of repairing the organic light emitting display apparatus of FIG. 11.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of exemplary implementations to those skilled in the art.

Accordingly, the drawings and description are to be regarded as illustrative in nature and not restrictive. Like reference numerals designate like elements throughout the specification. Sizes and thicknesses of the elements shown in the drawings are for the purpose of descriptive convenience, and thus embodiments are not limited thereto.

Thicknesses of layers and regions are expanded in the drawings for clarity. For descriptive convenience, thicknesses of some layers and regions are exaggerated in the drawings. When an element such as a layer, a film, a region, and a board is referred to as being “on” another element, the element can be directly on another element or intervening elements.

Throughout this specification, unless explicitly described to the contrary, the word “comprise” and variations such as “comprises” or “comprising”, will be understood to imply the inclusion of stated elements but not the exclusion of any other elements. Further, throughout this specification, the term “above” encompasses both an orientation of above and below and does not necessarily encompass the orientation of above with respect to a direction of gravity.

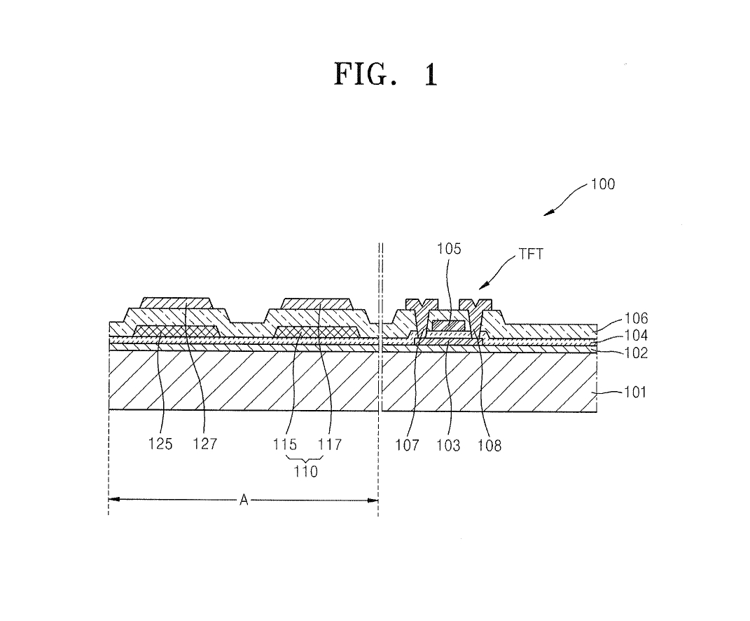

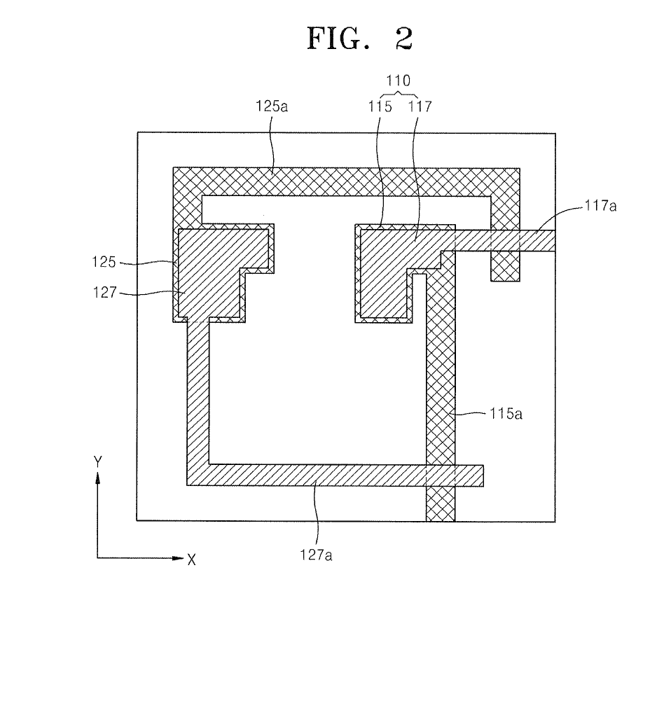

FIG. 1 is a schematic cross-sectional view of a thin film transistor (TFT) substrate 100 according to an exemplary embodiment. FIG. 2 is a top plan view of a region A of FIG. 1.

Referring to FIGS. 1 and 2, the TFT substrate 100 includes a substrate 101, a TFT, a capacitor 110, a first wire 115a, a second wire 117a, a first conductive pattern layer 125, a second conductive pattern layer 127, a first conductive wire pattern 125a, and a second conductive wire pattern 127a.

The TFT includes an active layer 103, a gate electrode 105, a source electrode 107, and a drain electrode 108. The capacitor 110 includes a first capacitor electrode 115 and a second capacitor electrode 117.

Although one TFT and one capacitor 110 are illustrated in the present embodiment, this is for convenience of description. The TFT substrate 100 may include a plurality of TFTs and capacitors 110. Likewise, the TFT substrate 100 may also include a plurality of first conductive pattern layers 125 and second conductive pattern layers 127.

Each element will now be described in detail.

The substrate 101 may be formed of a SiO₂-based transparent glass material. However, embodiments are not limited thereto, e.g., the substrate 101 may be formed of a transparent plastic material. The plastic material forming the substrate 101 may be one or more materials selected from various organic materials.

A buffer layer 102 is disposed on the substrate 101. The buffer layer 102 protects the substrate 101 against moisture and impure elements and provides a flat surface on the substrate 101. The buffer layer 102 may be formed of various materials capable of these functions. The buffer layer 102 is not an indispensable element and thus may be omitted.

An active layer 103 is formed on the buffer layer 102 of the substrate 101. The active layer 103 may contain various semiconductor materials, e.g., at least selected from a group of a silicon based inorganic semiconductor material, an organic semiconductor material, and an oxide semiconductor material.

A gate insulation layer 104 is formed on the active layer 103. The active layer 103 is insulated from a gate electrode 105 through the gate insulation layer 104.

The gate electrode 105 is formed on the gate insulation layer 104 and disposed to overlap with the active layer 103. The gate electrode 105 may contain Au, Ag, Cu, Ni, Pt, Pd, Al, and Mo, and contain an alloy such as an Al:Nd alloy, an Mo:W alloy, etc. However, embodiments are not limited thereto, e.g., the gate electrode 105 may be formed of various materials in consideration of adhesion, flatness, electrical resistance, a manufacturing process, and the like. For example, the gate electrode 105 may be formed with a neighboring layer.

The first capacitor electrode 115 of the capacitor 110 is formed on the gate insulation layer 104. The first capacitor electrode 115 may be formed of the same material as that of the gate electrode 105 and patterned simultaneously with the gate electrode 105. The first wire 115a is disposed to be connected the first capacitor electrode 115 so as to apply a voltage to the first capacitor electrode 115. This will be described in more detail later.

The first conductive pattern layer 125 is formed on the gate insulation layer 104. The first conductive pattern layer 125 is spaced apart from the first capacitor electrode 115. The first conductive pattern layer 125 may be formed of the same material as that of the gate electrode 105 and patterned simultaneously with the gate electrode 105.

The first conductive wire pattern 125a is disposed to be connected to the first conductive pattern layer 125. This will be described in more detail later.

An interlayer insulation layer 106 is formed on the gate electrode 105, the first capacitor electrode 115, and the first conductive pattern layer 125. The interlayer insulation layer 106 is formed on the first wire 115a and the first conductive wire pattern 125a.

The source electrode 107 and the drain electrode 108 are formed on the interlayer insulation layer 106. The source electrode 107 and the drain electrode 108 are formed to be spaced apart from the gate electrode 105 and connected to be the active layer 103.

The second capacitor electrode 117 of the capacitor 110 is formed on the interlayer insulation layer 106. The second capacitor electrode 117 may be formed of the same material as the source electrode 107 or the drain electrode 108 and patterned simultaneously with the source electrode 107 or the drain electrode 108. The second wire 117a is disposed to be connected the second capacitor electrode 117 so as to apply a voltage to the second capacitor electrode 117. This will be described in more detail later.

The second conductive pattern layer 127 is formed on the interlayer insulation layer 106 to overlap with the first conductive pattern layer 125. The second conductive pattern layer 127 is disposed to be spaced apart from the second capacitor electrode 117. The second conductive pattern layer 127 may be formed of the same material as the source electrode 107 or the drain electrode 108 and patterned simultaneously with the source electrode 107 or the drain electrode 108.

The second conductive wire pattern 127a is disposed to be connected to the second conductive pattern layer 127. This will be described in more detail later.

The capacitor 110, the first conductive pattern layer 125, and the second conductive pattern layer 127 will be described in more detail with reference to FIG. 2. FIG. 2 is a top plan view of a region A of FIG. 1.

The capacitor 110 may be disposed at various locations. That is, the capacitor 110 may be disposed to be adjacent to the TFT of the TFT substrate 100, and, in particular, electrically connected to the TFT. Also, embodiments are not limited thereto, e.g., the capacitor 110 may be disposed to be far away from the TFT.

Referring to FIG. 2, the first capacitor electrode 115 and the second capacitor 117 of the capacitor 110 are disposed to overlap with and be spaced apart from each other. The first capacitor electrode 115 is connected to the first wire 115a so that a voltage is applied to the first capacitor electrode 115 through the first wire 115a. The second capacitor electrode 117 is connected to the second wire 117a so that a voltage is applied to the second capacitor electrode 117 through the second wire 117a. That is, if the voltage is applied through the first wire 115a and the second wire 117a, charges are stored between the first capacitor electrode 115 and the second capacitor electrode 117.

The first conductive pattern layer 125 and the second conductive pattern layer 127 are disposed to overlap with and be spaced apart from each other. Also, the first conductive wire pattern 125a is connected to the first conductive pattern layer 125 and the second conductive wire pattern 127a is connected to the second conductive pattern layer 127.

The first conductive wire pattern 125a is formed to be spaced apart from the first wire 115a and the second wire 117a and overlap with at least the second wire 117a.

The second conductive wire pattern 127a is formed to be spaced apart from the first wire 115a and the second wire 117a and overlap with at least the first wire 115a.

That is, the first conductive pattern layer 125, the second conductive pattern layer 127, the first conductive wire pattern 125a, and the second conductive wire pattern 127a are in a state where no voltage is applied, i.e. a floating state. In particular, the first conductive pattern layer 125 and the second conductive pattern layer 127 completely float from the capacitor 110 electrically.

Thus, when the TFT substrate 100 normally operates, in particular, when no defect occurs in the capacitor 110, the first conductive pattern layer 125, the second conductive pattern layer 127, the first conductive wire pattern 125a, and the second conductive wire pattern 127a do not perform an electrical function but perform a dummy pattern function. For example, the first conductive pattern layer 125, the second conductive pattern layer 127, the first conductive wire pattern 125a, and the second conductive wire pattern 127a may be used as measure patterns that measure a patterning characteristic when various thin films included in the TFT substrate 100 is patterned, in particular, etch patterns.

However, in a case where a defect occurs in the TFT substrate 100, in particular, in the capacitor 110, the first conductive pattern layer 125, the second conductive pattern layer 127, the first conductive wire pattern 125a, and the second conductive wire pattern 127a may be used to repair the defect.

This repair process will now be described in more detail.

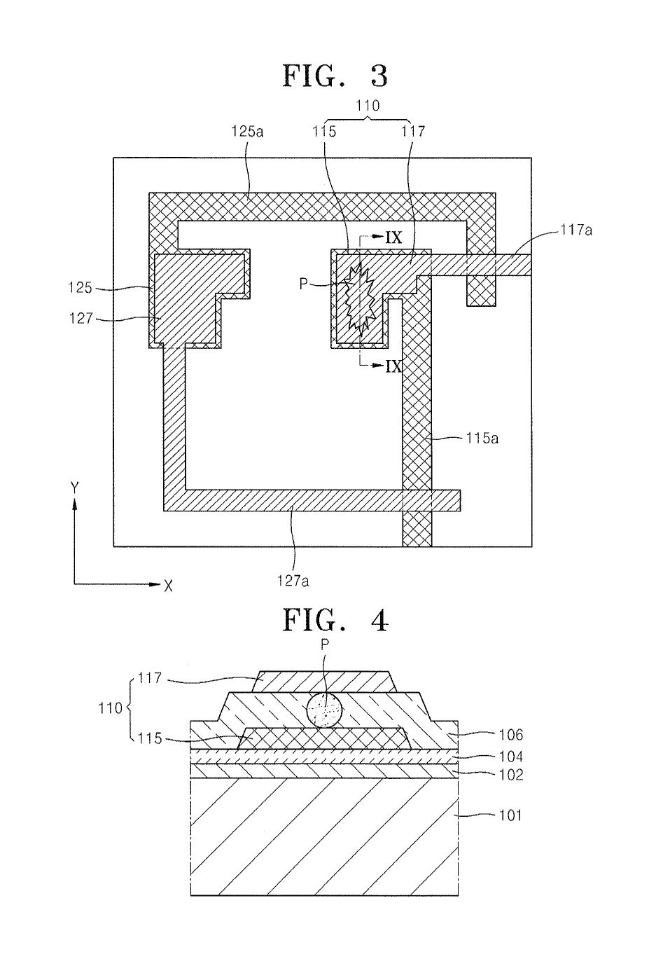

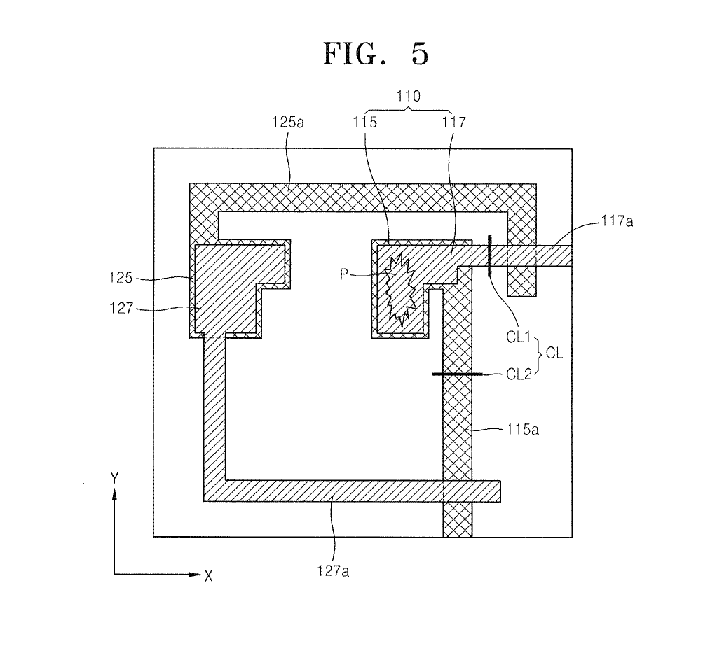

FIG. 3 is a plan view of the capacitor 110 of FIGS. 1 and 2 in which a short circuit defect occurs. FIG. 4 is a cross sectional view taken along a line IX-IX of FIG. 3.

Referring to FIGS. 3 and 4, a defect, more specifically, the short circuit defect, occurs in the capacitor 110 of the TFT substrate 100. The short circuit defect occurs due to various reasons. For example, a particle P inserted between the first capacitor electrode 115 and the second capacitor electrode 117 of the capacitor 110 may cause the short circuit defect. Such particle P may be introduced from the outside, or from a material remaining when each element, for example, the first capacitor electrode 115 or the second capacitor electrode 117, is patterned during the manufacture of the TFT substrate 100.

If such short circuit defect occurs in the capacitor 110, the capacitor 110 no longer performs its function. Thus, an electrical characteristic of the TFT substrate 100 deteriorates or the TFT substrate 100 malfunctions due to the short circuit defect of the capacitor 110.

The first conductive pattern layer 125, the second conductive pattern layer 127, the first conductive wire pattern 125a, and the second conductive wire pattern 127a may be used to prevent the electrical characteristic of the TFT substrate 100 from deteriorating or the TFT substrate 100 from malfunctioning.

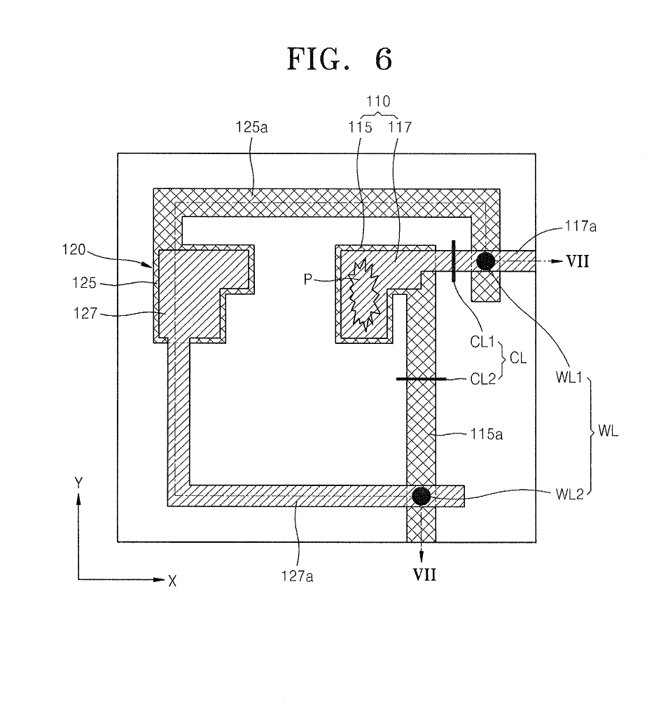

FIGS. 5 and 6 are plan views for explaining a method of repairing a TFT substrate of FIG. 3.

Referring to FIG. 5, a cutting member (not shown) is used to form a cutting portion CL.

The cutting portion CL includes a first cutting portion CL1 and a second cutting portion CL2. The cutting member (not shown) is used to form the first cutting portion CL1 in the second wire 117a and the second cutting portion CL2 in the first wire 115a.

The first cutting portion CL1 and the second cutting portion CL2 block voltages from being applied to the first capacitor electrode 115 and the second capacitor electrode 117, in which a short circuit defect has occurred, through the first wire 115a and the second wire 117a.

For example, the first cutting portion CL1 in the second wire 117a is formed closer to the second capacitor electrode 117 than an area in which the first conductive wire pattern 125a overlaps the second wire 117a.

The second cutting portion CL2 in the first wire 115a is formed closer to the first capacitor electrode 115 than an area in which the second conductive wire pattern 127a overlaps the first wire 115a.

Referring to FIG. 6, a welding portion WL is used to complete a repair process.

The welding portion WL includes a first welding portion WL1 and a second welding portion WL2. The first welding portion WL1 is formed at a location where the second wire 117a and the first conductive wire pattern 125a overlap with each other. The second welding portion WL2 is formed at a location where the first wire 115a and the second conductive wire pattern 127a overlap with each other.

The second wire 117a and the first conductive wire pattern 125a are electrically connected to each other through the first welding unit WL1. The first wire 115a and the second conductive wire pattern 127a are electrically connected to each other through the second welding unit WL2.

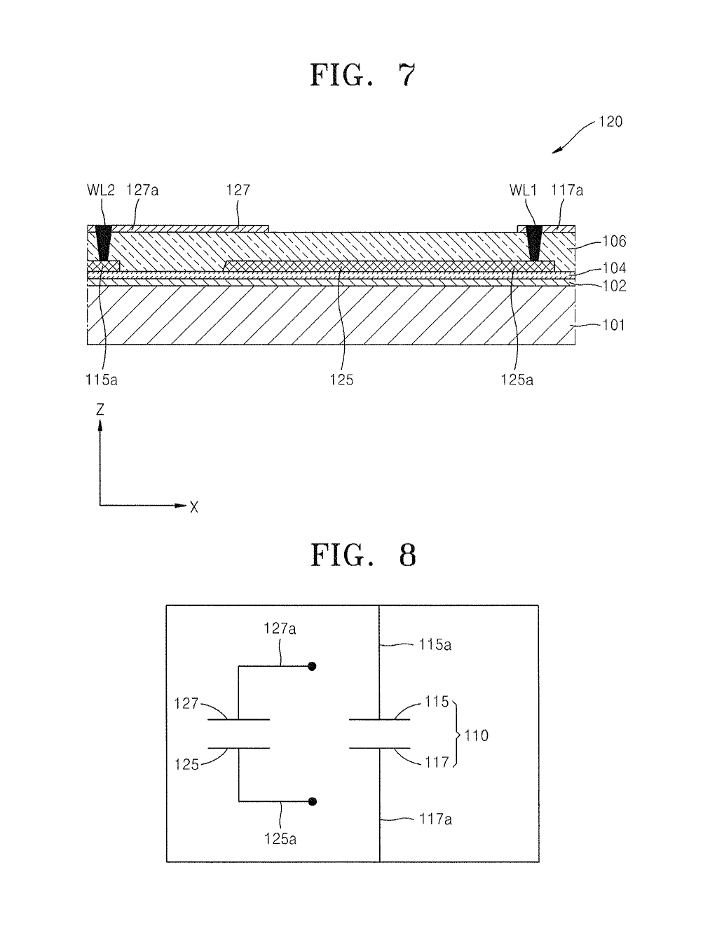

The first welding unit WL1 and the second welding unit WL2 will be described in more detail with reference to FIG. 7. FIG. 7 is a cross sectional view taken along a line VII-VII of FIG. 6.

Referring to FIG. 7, the first welding unit WL1 is formed by irradiating energy to the second wire 117a through a laser irradiation apparatus to melt a region of the second wire 117a, and formed by connecting the melted component to the first conductive wire pattern 125a through the interlayer insulation layer 106. As a result, the second wire 117a is electrically connected to the first conductive wire pattern 125 through the first conductive wire pattern 125a.

Also, the second welding unit WL2 is formed by irradiating energy to the second conductive wire pattern 127a through the laser irradiation apparatus to melt a region of the second conductive wire pattern 127a, and formed by connecting the melted component to the first wire 115a through the interlayer insulation layer 106. As a result, the first wire 115a is electrically connected to the second conductive pattern layer 127 through the second conductive wire pattern 127a.

Thus, a voltage may be applied to the second conductive pattern layer 127 through the second welding portion WL2 and the second conductive wire pattern 127a from the first wire 115a, and a voltage may be applied to the first conductive pattern layer 125 through the first welding portion WL1 and the first conductive wire pattern 125a from the second wire 117a. As a result, charge may be stored between the first conductive pattern layer 125 and the second conductive pattern layer 127 so that the first conductive pattern layer 125 and the second conductive pattern layer 127 may constitute a repair capacitor 120.

That is, in a case where the short circuit defect occurs in the capacitor 110 that normally operates, the repair capacitor 120 is formed by electrically isolating the defective capacitor 110 by forming the cutting portion CL through a cutting process, etc., and forming the welding portion WL through an energy irradiation such as a laser irradiation, etc. The repair capacitor 120 replaces the capacitor 110 in terms of a circuit, and thus the electrical characteristic of the TFT substrate 100 does not deteriorate. To more efficiently implement the repair capacitor 120, an overlapping area between the first conductive pattern layer 125 and the second conductive pattern layer 127 may be similar to an overlapping area between the first capacitor electrode 115 and the second capacitor electrode 117 in such a manner that capacitance of the repair capacitor 120 may be similar to capacitance of the capacitor 110.

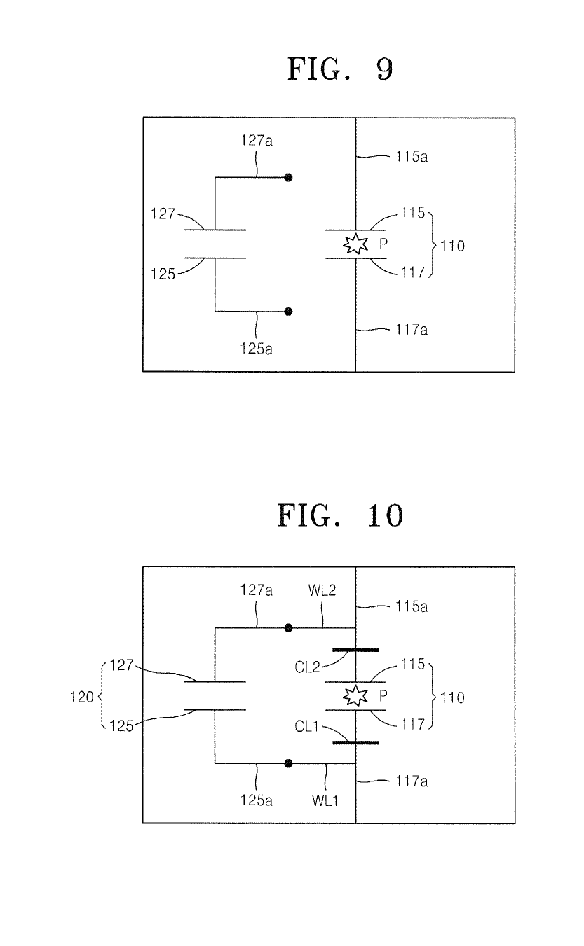

The repair process will now be described in brief with reference to FIGS. 8 through 10.

FIGS. 8 through 10 are schematic circuit diagrams for sequentially explaining a method of repairing a short circuit defect that occurs in a TFT substrate of FIG. 1.

Referring to FIG. 8, the capacitor 110 normally operates, and the first conductive pattern layer 125, the second conductive pattern layer 127, the first conductive wire pattern 125a, and the second conductive wire pattern 127a electrically float. That is, the first conductive pattern layer 125, the second conductive pattern layer 127, the first conductive wire pattern 125a, and the second conductive wire pattern 127a function as electrically isolated dummy patterns.

Referring to FIG. 9, the particle P occurs between the first capacitor electrode 115 and the second capacitor electrode 117 of the capacitor 110 and the short circuit defect has occurred. Thus, the capacitor 110 loses a normal function.

Referring to FIG. 10, the second cutting portion CL2 is formed in the first wire 115a and the first cutting portion CL1 is formed in the second wire 117a by using a cutting member to block a voltage applied to the capacitor 110 when the capacitor 110 has lost the normal function. The first welding portion WL1 is formed to electrically connect the first conductive wire pattern 125a and the second wire 117a. The second welding portion WL2 is formed to electrically connect the second conductive wire pattern 127a and the first wire 115a. Thus, the first conductive wire pattern 125a and the second conductive wire pattern 127a perform functions of capacitor electrodes to constitute the repair capacitor 120.

The repair capacitor 120 replaces a function of the capacitor 110 in which the defect finally occurs, and thus the electrical characteristic of the TFT substrate 100 may be uniformly maintained.

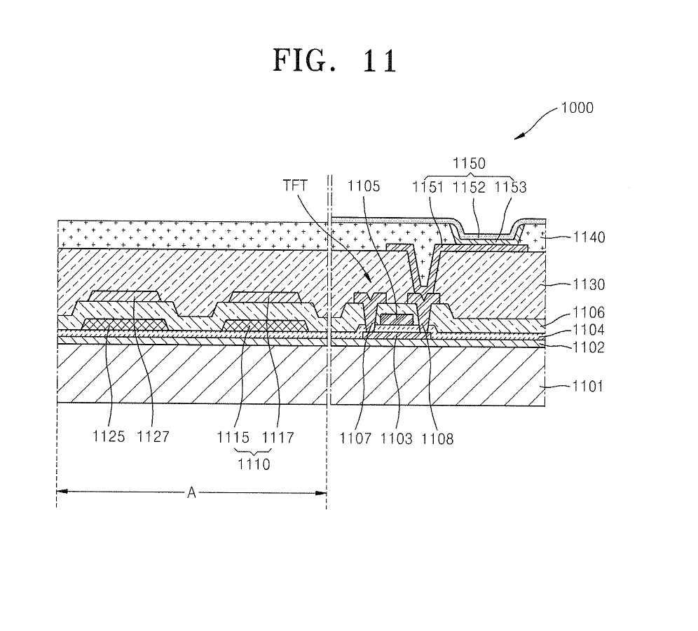

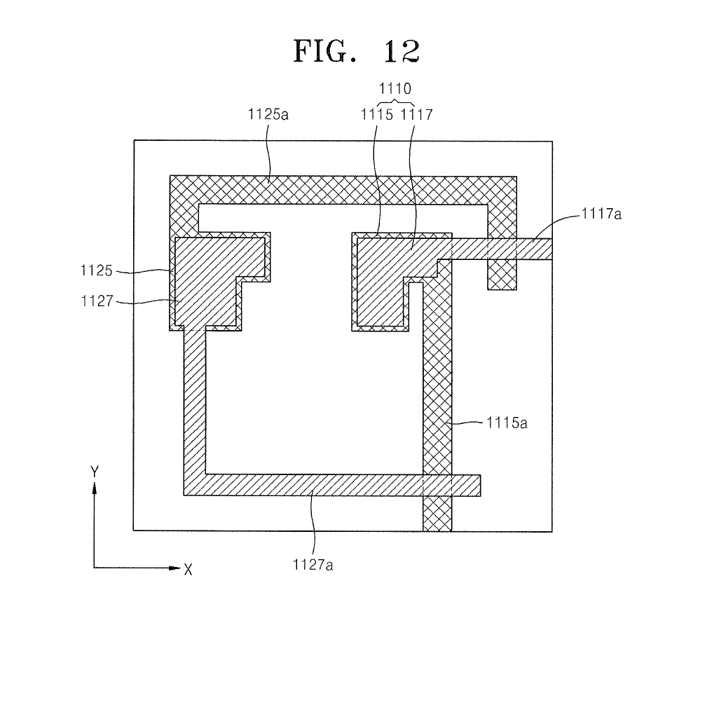

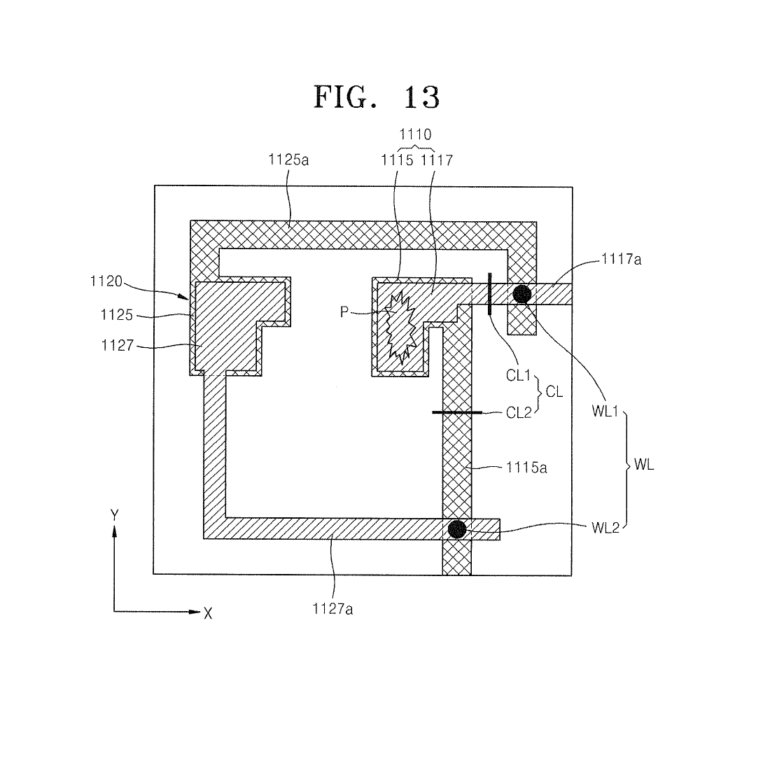

FIG. 11 is a schematic cross-sectional view of an organic light emitting display apparatus 1000 according to an exemplary embodiment. FIG. 12 is a top plan view of a region A of FIG. 11. FIG. 13 is a plan view for explaining a method of repairing the organic light emitting display apparatus 1000 of FIG. 11.

For convenience of description, differences between the present embodiment and the previous embodiment will now be described, and partial descriptions of redundant elements therebetween are omitted.

Referring to FIGS. 11 and 12, the organic light emitting display apparatus 1000 includes a substrate 1101, an organic light emitting device (OLED) 1150, a TFT, a capacitor 1110, a first wire 1115a, a second wire 1117a, a first conductive pattern layer 1125, a second conductive pattern layer 1127, a first conductive wire pattern 1125a, and a second conductive wire pattern 1127a.

The OLED 1150 includes a first electrode 1151, an intermediate layer 1153, and a second electrode 1152.

The TFT includes an active layer 1103, a gate electrode 1105, a source electrode 1107, and a drain electrode 1108. The capacitor 1110 includes a first capacitor electrode 1115 and a second capacitor electrode 1117.

Each element will now be described in detail.

The buffer layer 1102 is disposed on the substrate 1101. The buffer layer 1102 is not an indispensable element and thus may be omitted.

An active layer 1103 is formed on the buffer layer 1102 of the substrate 1101. A gate insulation layer 1104 is formed on the active layer 1103. The active layer 1103 may contain various semiconductor materials, for example, an inorganic semiconductor, an organic semiconductor, or an oxide semiconductor as described in the previous embodiment.

The gate electrode 1105 is formed on the gate insulation layer 1104 and disposed to overlap with the active layer 1103.

The first capacitor electrode 1115 of the capacitor 1110 is formed on the gate insulation layer 1104. The first capacitor electrode 1115 may be formed of the same material as that of the gate electrode 1105 and patterned simultaneously with the gate electrode 1105. The first wire 1115a is disposed to be connected the first capacitor electrode 1115 so as to apply a voltage to the first capacitor electrode 1115.

The first conductive pattern layer 1125 is formed on the gate insulation layer 1104. The first pattern layer 1125 is spaced apart from the first capacitor electrode 1115. The first conductive pattern layer 1125 may be formed of the same material as that of the gate electrode 1105 and patterned simultaneously with the gate electrode 1105.

The first conductive wire pattern 1125a is disposed to be connected to the first conductive pattern layer 1125.

An interlayer insulation layer 1106 is formed on the gate electrode 1105, the first capacitor electrode 1115, and the first conductive pattern layer 1125. The interlayer insulation layer 1106 is formed on the first wire 1115a and the first conductive wire pattern 1125a.

The source electrode 1107 and the drain electrode 1108 are formed on the interlayer insulation layer 1106. The source electrode 1107 and the drain electrode 1108 are formed to be spaced apart from the gate electrode 1105 and connected to be the active layer 1103.

The second capacitor electrode 1117 of the capacitor 1110 is formed on the interlayer insulation layer 1106. The second capacitor electrode 1117 may be formed of the same material as the source electrode 1107 or the drain electrode 1108 and patterned simultaneously with the source electrode 1107 or the drain electrode 1108. The second wire 1117a is disposed to be connected the second capacitor electrode 1117 so as to apply a voltage to the second capacitor electrode 1117.

The second conductive pattern layer 1127 is formed on the interlayer insulation layer 1106. The second conductive pattern layer 1127 is disposed to be spaced apart from the second capacitor electrode 1117. The second conductive pattern layer 1127 may be formed of the same material as the source electrode 1107 or the drain electrode 1108 and patterned simultaneously with the source electrode 1107 or the drain electrode 1108.

The second conductive wire pattern 1127a is disposed to be connected to the second conductive pattern layer 1127.

A passivation layer 1130 is formed on the source electrode 1107 or the drain electrode 1108. In this regard, the passivation layer 1130 may be formed on the second capacitor electrode 1117 and the second conductive pattern layer 1127.

The first electrode 1151 is formed on the passivation layer 1130. The passivation layer 1130 is formed to expose a predetermined region of the drain electrode 1108 without covering the entire of the drain electrode 1108. The first electrode 1151 is formed to be connected to the exposed area of the drain electrode 1108.

The first electrode 1151 may act as an anode, and the second electrode 1152 may act as a cathode. Polarities of the first and second electrodes 1151 and 1152 may be switched.

In a case where the first electrode 1151 act as the anode, the first electrode 1151 may include ITO, IZO, ZnO, or In2O3 having a high work function. Also, the first electrode 1151 may further include a reflective layer formed of Ag, Mg, Al, Pt, Pd, Au, Ni, Nd, Ir, Cr, Li, Yb, or Ca according to an objective and design conditions.

A pixel definition layer 1140 is formed on the first electrode 1151 using an insulation material. In this regard, the pixel definition layer 1140 is formed to expose at least a part of an upper surface of the first electrode 1151. The intermediate layer 1153 is formed on the exposed upper surface of the first electrode 1151.

The intermediate layer 1153 includes an organic emissive layer so as to implement a visible ray. Also, the intermediate layer 1153 may selectively include one or more layers from a hole injection layer (HIL), a hole transport layer (HTL), an electron transport layer (ETL), and an electron injection layer (EIL).

The second electrode 1152 is formed on the intermediate layer 1153. In a case where the second electrode 1152 serves as the cathode, the second electrode 1152 may be formed of Ag, Mg, Al, Pt, Pd, Au, Ni, Nd, Ir, Cr, Li, or Ca. Also, the second electrode 1152 may include ITO, IZO, ZnO, or In2O3 so as to pass through light.

Although not shown, an encapsulating member may be formed on the second electrode 1152. The encapsulating member (not shown) may be formed of various materials, may use a substrate formed of a glass material, or an organic layer and an inorganic layer that are alternately disposed.

The capacitor 1110, the first conductive pattern layer 1125, and the second conductive pattern layer 1127 will now be described in more detail with reference to FIG. 12. FIG. 12 is a top plan view of a region A of FIG. 11.

The capacitor 1110 may be disposed at various locations. That is, the capacitor 110 may be disposed to be adjacent to the TFT of the organic light emitting display apparatus 1000, and, in particular, electrically connected to the TFT.

Also, embodiments are not limited thereto, e.g., the capacitor 1110 may be disposed to be far away from the TFT. For example, the capacitor 1110 may be disposed at a circuit area disposed in a boundary of an area in which an image of the organic light emitting display apparatus 1000 is implemented.

Referring to FIG. 12, the first capacitor electrode 1115 and the second capacitor 1117 of the capacitor 1110 are disposed to overlap with and be spaced apart from each other. The first capacitor electrode 1115 is connected to the first wire 1115a so that a voltage is applied to the first capacitor electrode 1115 through the first wire 1115a. The second capacitor electrode 1117 is connected to the second wire 1117a so that a voltage is applied to the second capacitor electrode 1117 through the second wire 1117a. That is, if the voltage is applied through the first wire 1115a and the second wire 1117a, charges are stored between the first capacitor electrode 1115 and the second capacitor electrode 1117.

The first conductive pattern layer 1125 and the second conductive pattern layer 1127 are disposed to overlap with and be spaced apart from each other. Also, the first conductive wire pattern 1125a is connected to the first conductive pattern layer 1125 and the second conductive wire pattern 1127a is connected to the second conductive pattern layer 1127.

The first conductive wire pattern 1125a is formed to be spaced apart from the first wire 1115a and the second wire 1117a and overlap with at least the second wire 1117a.

The second conductive wire pattern 1127a is formed to be spaced apart from the first wire 1115a and the second wire 1117a and overlap with at least the first wire 115a.

That is, the first conductive pattern layer 1125, the second conductive pattern layer 1127, the conductivefirst conductive wire pattern 1125a, and the second conductive wire pattern 1127a are in a state where no voltage is applied, i.e. a floating state. In particular, the first conductive pattern layer 1125 and the second conductive pattern layer 1127 completely float from the capacitor 1110 electrically.

Thus, when the organic light emitting display apparatus 1000 normally operates, in particular, when no defect occurs in the capacitor 1110, the first conductive pattern layer 1125, the second conductive pattern layer 1127, the conductivefirst conductive wire pattern 1125a, and the second conductive wire pattern 1127a do not perform an electrical function but perform a dummy pattern function. For example, the first conductive pattern layer 1125, the second conductive pattern layer 1127, the conductivefirst conductive wire pattern 1125a, and the second conductive wire pattern 1127a may be used as measure patterns that measure a patterning characteristic when various thin films included in the organic light emitting display apparatus 1000 is patterned, in particular, etch patterns.

However, in a case where a defect occurs in the capacitor 1110, in particular, in the capacitor 1110, the first conductive pattern layer 1125, the second conductive pattern layer 1127, the conductivefirst conductive wire pattern 1125a, and the second conductive wire pattern 1127a may be used to repair the defect.

This repair process will now be described in more detail.

FIG. 13 is a plan view for explaining a method of repairing the organic light emitting display apparatus 1000 of FIG. 11.

Referring to FIG. 13, a method of repairing a defect, more specifically, a short circuit defect, that occurs in the capacitor 1110 is illustrated.

The particle P inserted between the first capacitor electrode 1115 and the second capacitor electrode 1117 of the capacitor 1110 causes the short circuit defect.

A cutting member (not shown) is used to form the cutting portion CL. The cutting portion CL includes the first cutting portion CL1 and the second cutting portion CL2. The cutting member (not shown) is used to form the first cutting portion CL1 in the second wire 1117a and the second cutting portion CL2 in the first wire 1115a.

The first cutting portion CL1 and the second cutting portion CL2 block voltages from being applied to the first capacitor electrode 1115 and the second capacitor electrode 1117 in which the short circuit defect occurs through the first wire 1115a and the second wire 1117a.

In more detail, the first cutting portion CL1 is formed closer to the second capacitor electrode 1117 than an area that overlaps with the first conductive wire pattern 1125a in an area of the second wire 1117a.

The second cutting portion CL2 is also formed closer to the first capacitor electrode 1115 than an area that overlaps with the second conductive wire pattern 1127a in an area of the first wire 1115a.

The welding portion WL is formed using various energy irradiation apparatuses such as a laser irradiation apparatus.

The welding portion WL includes the first welding portion WL1 and the second welding portion WL2. The first welding portion WL1 is formed at a location where the second wire 1117a and the first conductive wire pattern 1125a overlap with each other. The second welding portion WL2 is formed at a location where the first wire 1115a and the second wire pattern 1127a overlap with each other.

The second wire 1117a and the first conductive wire pattern 1125a are electrically connected to each other through the first welding unit WL1. The first wire 1115a and the second conductive wire pattern 1127a are electrically connected to each other through the second welding unit WL2.

In more detail, the first welding unit WL1 is formed by irradiating energy to the second wire 1117a through a laser irradiation apparatus to melt a region of the second wire 1117a, and formed by connecting the melted component to the first conductive wire pattern 1125a through the interlayer insulation layer 1106. As a result, the second wire 1117a is electrically connected to the first conductive wire pattern 1125 through the first conductive wire pattern 1125a.

Also, the second welding unit WL2 is formed by irradiating energy to the second conductive wire pattern 1127a through the laser irradiation apparatus to melt a region of the second conductive wire pattern 1127a, and formed by connecting the melted component to the first wire 1115a through the interlayer insulation layer 1106. As a result, the first wire 1115a is electrically connected to the second conductive pattern layer 1127 through the second conductive wire pattern 1127a.

Thus, a voltage may be applied to the second conductive pattern layer 1127 through the second welding portion WL2 and the second conductive wire pattern 1127a from the first wire 1115a, and a voltage may be applied to the first conductive pattern layer 1125 through the first welding portion WL1 and the first conductive wire pattern 1125a from the second wire 1117a. As a result, charges may be stored between the first conductive pattern layer 1125 and the second conductive pattern layer 1127 so that the first conductive pattern layer 1125 and the second conductive pattern layer 1127 may constitute a repair capacitor 1120.

That is, in a case where the short circuit defect occurs in the capacitor 1110 that normally operates, the repair capacitor 1120 is formed by electrically isolating the defective capacitor 1110 by forming the cutting portion CL through a cutting process, etc., and forming the welding portion WL through an energy irradiation such as a laser irradiation, etc. The repair capacitor 1120 replaces the capacitor 1110 in terms of a circuit, and thus the electrical characteristic of a TFT substrate 1100 does not deteriorate. To more efficiently implement the repair capacitor 1120, an overlapping area between the first conductive pattern layer 1125 and the second conductive pattern layer 1127 may be similar to an overlapping area between the first capacitor electrode 1115 and the second capacitor electrode 1117 in such a manner that capacitance of the repair capacitor 1120 may be similar to capacitance of the capacitor 1110.

In a case where a defect such as a short circuit defect occurs in the capacitor 1110 of the organic light emitting display apparatus 1000, the repair capacitor 1120 replaces a function of the capacitor 1110 in which the defect occurs, and thus the electrical characteristic of the TFT substrate 1100 may be uniformly maintained.

By way of summation and review, an organic light emitting display apparatus may have a larger viewing angle, better contrast characteristics, and/or a faster response speed compared to other flat panel display apparatuses. The organic light emitting display apparatus may include an intermediate layer, a first electrode, and a second electrode. The intermediate layer may include an organic emission layer that generates visible light when voltages are applied to the first electrode and the second electrode.

The organic light emitting display apparatus may be manufactured using a thin film transistor (TFT) substrate including one or more TFTs. Such a TFT substrate may include one or more capacitors to implement various electrical characteristics in addition to the TFTs. However, in a case where particles and other impurities are penetrated into a capacitor, a short circuit defect may occur in the capacitor, which deteriorates an electrical characteristic of the TFT substrate.

In contrast, embodiments relate to an enhancement of the electrical characteristic of the organic light emitting display apparatus. For example, embodiments relates to a TFT substrate that improves an electrical characteristic, a method of repairing the TFT substrate, an organic light emitting display apparatus, and a method of manufacturing the organic light emitting display apparatus. The TFT substrate, a method of repairing the TFT substrate, an organic light emitting display apparatus, and a method of manufacturing the organic light emitting display apparatus according to embodiments may easily improve an electrical characteristic.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A thin film transistor (TFT) substrate, comprising:
a substrate;
a TFT on the substrate, the TFT including an active layer, a gate electrode insulated from the active layer, and a source electrode and a drain electrode that are spaced apart from the gate electrode and connected to the active layer;
a capacitor on the substrate, the capacitor including a first capacitor electrode and a second capacitor electrode;
a first wire connected to the first capacitor electrode so as to apply a voltage to the first capacitor electrode;
a second wire connected to the second capacitor electrode so as to apply a voltage to the second capacitor electrode;
a first conductive pattern layer spaced apart from the first capacitor electrode and the second capacitor electrode;
a second conductive pattern layer spaced apart from the first conductive pattern layer, the second conductive pattern layer overlapping the first conductive pattern layer;
a first conductive wire pattern connected to the first conductive pattern layer, spaced apart from the second conductive pattern layer, and overlapping the second wire; and
a second conductive wire pattern connected to the second conductive pattern layer, spaced apart from the first conductive pattern layer and the first conductive wire pattern, and overlapping the first wire.

2. The TFT substrate of claim 1, wherein the first conductive pattern layer and the first capacitor electrode are formed on a same layer and formed of a same material.

3. The TFT substrate of claim 1, wherein the second conductive pattern layer and the second capacitor electrode are formed on a same layer and formed of a same material.

4. The TFT substrate of claim 1, wherein the first conductive pattern layer and the gate electrode are formed on a same layer and formed of a same material.

5. The TFT substrate of claim 1, wherein the second conductive pattern layer and the source electrode or the drain electrode are formed on a same layer and formed of a same material.

6. The TFT substrate of claim 1, wherein:
a voltage application passage to the capacitor is configured to be blocked when a short circuit defect occurs in the capacitor based on particles and impurities being disposed between the first capacitor electrode and the second capacitor electrode, and
the first conductive pattern layer and the second conductive pattern layer are configured to constitute a repair capacitor that replaces a function of the capacitor when the short circuit defect occurs.

7. The TFT substrate of claim 6, wherein:
the voltage application passage is configured to be blocked by a first cutting portion and a second cutting portion,
the first cutting portion is in an area closer to the second capacitor electrode than an area in which the first conductive wire pattern overlaps the second wire, and
the second cutting portion is in an area closer to the first capacitor electrode than an area in which the second conductive wire pattern overlaps the first wire.

8. The TFT substrate of claim 7, further comprising:
a first welding portion at the area in which the first conductive wire pattern overlaps the second wire, the first welding portion connecting the first conductive wire pattern and the second wire; and
a second welding portion at the area in which the second conductive wire pattern overlaps the first wire, the second welding portion connecting the second conductive wire pattern and the first wire.

9. The TFT substrate of claim 1, wherein the first conductive pattern layer or the second conductive pattern layer performs a dummy pattern function when a short circuit defect has not occurred in the capacitor.

10. A method of repairing a thin film transistor (TFT) substrate, the TFT substrate including a substrate, a TFT on the substrate, a capacitor on the substrate, which capacitor includes a first capacitor electrode and a second capacitor electrode, a first conductive pattern layer that is spaced apart from the first capacitor electrode and the second capacitor electrode, a second conductive pattern layer that is spaced apart from the first conductive pattern layer and that overlaps the first conductive pattern layer, a first conductive wire pattern that is connected to the first conductive pattern layer and that is spaced apart from the second conductive pattern layer, and a second conductive wire pattern that is connected to the second conductive pattern layer and that is spaced apart from the first conductive pattern layer and the first conductive wire pattern, the method comprising:
blocking a voltage from being applied to the capacitor when a short circuit defect occurs in the capacitor based on particles and other impurities being disposed between the first capacitor electrode and the second capacitor electrode; and
forming a repair capacitor with the first conductive pattern layer and the second conductive pattern layer, the repair capacitor replacing a function of the capacitor.

11. The method of claim 10, wherein the blocking of the voltage from being applied to the capacitor includes:
forming a first cutting portion with a cutting member by cutting an area closer to the second capacitor electrode than an area in which the first conductive wire pattern overlaps a second wire formed to apply a voltage to the second capacitor electrode, and
forming a second cutting portion with the cutting member by cutting an area closer to the first capacitor electrode than an area in which the second conductive wire pattern overlaps a first wire formed to apply a voltage to the first capacitor electrode.

12. The method of claim 11, further comprising:
forming a first welding portion at the area in which the first conductive wire pattern overlaps the second wire by irradiating energy so as to connect the first conductive wire pattern and the second wire; and
forming a second welding portion at the area in which the second conductive wire pattern overlaps the first wire by irradiating energy so as to connect the second conductive wire pattern and the first wire.

13. An organic light emitting display apparatus, comprising:
a substrate;
an organic light emitting device (OLED) on the substrate, the OLED including a first electrode, a second electrode, and an intermediate layer between the first electrode and the second electrode, the intermediate layer including an organic emissive layer;
a capacitor on the substrate, the capacitor including a first capacitor electrode and a second capacitor electrode;
a first wire connected to the first capacitor electrode so as to apply a voltage to the first capacitor electrode;
a second wire connected to the second capacitor electrode so as to apply a voltage to the second capacitor electrode;
a first conductive pattern layer spaced apart from the first capacitor electrode and the second capacitor electrode;
a second conductive pattern layer spaced apart from the first conductive pattern layer, the second conductive pattern layer overlapping the first conductive pattern layer;
a first conductive wire pattern connected to the first conductive pattern layer, spaced apart from the second conductive pattern layer, and overlapping the second wire; and
a second conductive wire pattern connected to the second conductive pattern layer, spaced apart from the first conductive pattern layer and the first conductive wire pattern, and overlapping the first wire.

14. The organic light emitting display apparatus of claim 13, wherein the first conductive pattern layer and the first capacitor electrode are formed on a same layer and formed of a same material.

15. The organic light emitting display apparatus of claim 13, wherein the second conductive pattern layer and the second capacitor electrode are formed on a same layer and formed of a same material.

16. The organic light emitting display apparatus of claim 13, further comprising a thin film transistor (TFT) on the substrate, the TFT including an active layer, a gate electrode insulated from the active layer, and a source electrode and a drain electrode that are spaced apart from the gate electrode and connected to the active layer,
wherein the first conductive pattern layer and the gate electrode are formed on a same layer and formed of a same material.

17. The organic light emitting display apparatus of claim 13, wherein:
a voltage application passage to the capacitor is configured to be blocked when a short circuit defect occurs in the capacitor based on particles and impurities being disposed between the first capacitor electrode and the second capacitor electrode, and
the first conductive pattern layer and the second conductive pattern layer are configured to constitute a repair capacitor that replaces a function of the capacitor when the short circuit defect occurs.

18. The organic light emitting display apparatus of claim 17, wherein:
the voltage application passage is configured to be blocked by a first cutting portion and a second cutting portion,
the first cutting portion is in an area closer to the second capacitor electrode than an area in which the first conductive wire pattern overlaps the second wire, and
the second cutting portion is in an area closer to the first capacitor electrode than an area in which the second conductive wire pattern overlaps the first wire.

19. The organic light emitting display apparatus of claim 18, further comprising:
a first welding portion at the area in which the first conductive wire pattern overlaps the second wire, the first welding portion connecting the first conductive wire pattern and the second wire; and
a second welding portion at the area in which the second conductive wire pattern overlaps the first wire, the second welding portion connecting the second conductive wire pattern and the first wire.

20. The organic light emitting display apparatus of claim 13, wherein the capacitor is in a display area in which an image of the organic light emitting display apparatus is implemented.

21. The organic light emitting display apparatus of claim 13, wherein the capacitor is in a circuit area at a periphery of the display area.

22. The organic light emitting display apparatus of claim 13, wherein the first conductive pattern layer or the second conductive pattern layer performs a dummy pattern function when a short circuit defect has not occurred in the capacitor.

23. A method of repairing an organic light emitting display apparatus, the organic light emitting display apparatus including a substrate, an organic light emitting device (OLED) on the substrate, which OLED includes a first electrode, a second electrode, and an intermediate layer that is between the first electrode and the second electrode and that includes at least an organic emissive layer, a capacitor on the substrate, which capacitor includes a first capacitor electrode and a second capacitor electrode, a first conductive pattern layer that is spaced apart from the first capacitor electrode and the second capacitor electrode, a second conductive pattern layer that is spaced apart from the first conductive pattern layer and that overlaps the first conductive pattern layer, a first conductive wire pattern that is connected to the first conductive pattern layer and that is spaced apart from the second conductive pattern layer, and a second conductive wire pattern that is connected to the second conductive pattern layer and that is spaced apart from the first conductive pattern layer and the first conductive wire pattern, the method comprising:
blocking a voltage from being applied to the capacitor when a short circuit defect occurs in the capacitor based on particles and other impurities being disposed between the first capacitor electrode and the second capacitor electrode; and
forming a repair capacitor with the first conductive pattern layer and the second conductive pattern layer, the repair capacitor replacing a function of the capacitor.

24. The method of claim 23, wherein the blocking of the voltage from being applied to the capacitor includes:
forming a first cutting portion with a cutting member by cutting an area closer to the second capacitor electrode than an area in which the first conductive wire pattern overlaps a second wire formed to apply a voltage to the second capacitor electrode, and
forming a second cutting portion with the cutting member by cutting an area closer to the first capacitor electrode than an area in which the second conductive wire pattern overlaps a first wire formed to apply a voltage to the first capacitor electrode.

25. The method of claim 24, further comprising:
forming a first welding portion at the area in which the first conductive wire pattern overlaps the second wire by irradiating energy so as to connect the first conductive wire pattern and the second wire; and
forming a second welding portion at the area in which the second conductive wire pattern overlaps the first wire by irradiating energy so as to connect the second conductive wire pattern and the first wire.
